(19) United States
(12) Patent Application Publication
(10) Pub. No.: US 2024/0222110 A1
(43) Pub. Date: Jul. 4, 2024

(54) PARTIAL BREAKDOWN OF PRECURSORS FOR ENHANCED ALD FILM GROWTH

(71) Applicant: ASM IP Holding B.V., Almere (NL)

(72) Inventors: Tommi Tynell, Espoo (FI); Viljami J. Pore, Helsinki (FI)

(21) Appl. No.: 18/395,907

(22) Filed: Dec. 26, 2023

Related U.S. Application Data
(60) Provisional application No. 63/477,748, filed on Dec. 29, 2022.

(51) Int. Cl. H01L 21/02; H01J 37/302; H01J 37/32

(52) U.S. Cl. CPC H01L 21/02274; H01J 37/3023; H01J 37/32357

(57) ABSTRACT

The present disclosure relates to methods and systems for forming a film using atomic layer deposition (ALD). More particularly, the disclosed methods and systems utilize a remote low-power plasma to partially breakdown a chemical precursor to form a radicalized precursor which more efficiently chemisorbs onto the surface of a substrate. A second reactant is introduced to convert the chemisorb layer into the desired film.

### CROSS-REFERENCE TO RELATED APPLICATION(S)

This application claims the benefit of U.S. Provisional Application 63/477,748 filed on Dec. 29, 2022, the entire contents of which are incorporated herein by reference.

### FIELD OF INVENTION

The present disclosure relates to methods and systems for depositing a thin film on the surface of a substrate using plasma enhance atomic-layer deposition (PE-ALD), and in particular to the use of a low-power plasma to affect partial breakdown of chemical precursors.

### BACKGROUND OF THE DISCLOSURE

Atomic layer deposition (ALD) is a method of depositing a thin film on the surface of a substrate, by sequentially exposing a substrate to two or more gas-phase chemical reactants. ALD processes are typically based on controlled, often self-limiting surface reactions of chemical reactants. In its simple form, a first precursor (reactant) is introduced into a reaction chamber whereby it chemisorbs onto the surface of a substrate forming a monolayer (or sub-monolayer) on the surface. Thereafter, a second reactant is introduced into the reaction chamber whereby it reacts with the previously deposited layer to form a thin film. The process is sequentially repeated to grow a film of desired thickness. More complicated ALD processes can include three, four, or more reactants or additional process steps. Because the reactions with the surface are generally self-limiting, ALD provides for precise control over the film thickness and uniform and conformal coverage of the substrate can be obtained. However, the process is generally slow (compared to other thin film deposition processes) and it is highly temperature dependent. If the substrate temperature is too high, desorption of the chemisorbed layer occurs. If the temperature is too low, the deposition reaction may be too slow and the reaction may not proceed to completion or not at all, leading to poor film quality. Thus, the narrow temperature window limits the number of suitable precursors in traditional thermal ALD processes.

Plasma-enhanced ALD (PE-ALD) may be used to overcome some of the limitations of thermal ALD processes. In these methods, a plasma is employed during at least one of the reaction steps. The use of energetic plasma species, such as radicals, as reactants increases the reactivity, allows for lower temperature processing and, in many instances, provides improved film properties (e.g., density, impurity level, and electronic properties). Various reactor configurations may be employed to influence the types and density of the plasma species that interact with the substrate. In direct PE-ALD, a plasma is created in close proximity to the substrate surface. The flux of energetic species (e.g., ions, radicals, etc.) can be high allowing for uniform film formation and short plasma exposure times, but plasma induced damage and anisotropy in the film can also occur. In remote PE-ALD, the plasma is located further away from the substrate surface, reducing, but not eliminating, the flux of ions to the substrate surface. In contrast, in radical enhanced ALD (RE-ALD), which is a type of PE-ALD, ions are prevented from reaching the substrate surface and film growth relies on the reactive radicals in the plasma. This approach avoids the plasma induced damage and anisotropy often associated with PE-ALD processes, while still providing an advantage in reactivity over thermal ALD processing.

Typically, plasmas used during PE-ALD methods are used to enhance conversion of the chemisorbed layer. Plasmas are generated using reactive gasses (e.g., O₂, N₂, NH₃, H₂, etc.) to form radicals and/or excited species which then react with the chemisorbed layer. The use of radicals and/or excited species as reactants allows for a wider selection of precursors with higher thermal and chemical stabilities. For example, certain metal β-diketonate precursors react with H radicals to form metal films or with O radicals to form metal oxide films, but do not readily react with H₂ or H₂O in the corresponding thermal processes. New ALD processes are being sought continuously and plasma-assisted processes are considered an enabler for a wide range of applications.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

An aspect of the present disclosure is a method for forming a film on a surface of a substrate, comprising: providing a substrate in a reaction chamber; providing a first precursor into a low-power plasma discharge to form a radicalized first precursor; contacting a surface of the substrate with the radicalized first precursor, wherein at least a portion of the radicalized first precursor chemisorbs onto the surface of the substrate to form a chemisorbed layer; and contacting the surface of the substrate with a reactive gas, wherein at least a portion of the reactive gas reacts with the chemisorbed layer to form a film. The method may further comprise, providing a second plasma discharge, wherein the second plasma discharge comprises the reactive gas. The method may further comprise, purging the reaction chamber prior to contacting the surface of the substrate with the reactive gas and/or purging the reaction chamber prior to providing the first precursor into the low-power plasma discharge. The method may further comprise, sequentially repeating the contacting steps and optionally the purging steps to grow the film to a target thickness on the surface of the substrate.

Another aspect of the disclosure is a system, for example an apparatus, comprising: a reaction chamber for accommodating a substrate; a first source for a first precursor in gas communication via a first valve with the reaction chamber; a second source for a reactive gas in gas communication via a second valve with the reaction chamber; a plasma unit comprising a radio-frequency (RF) power source; and a controller operably connected to the first valve, the second valve, and the plasma unit. The controller is configured and programmed to control: supplying the first precursor into the reaction chamber; activating the plasma unit to supply a low-power plasma discharge in the reaction chamber to form a radicalized first precursor from the first precursor, wherein at least a portion of the radicalized first precursor chemisorbs onto a surface of the substrate to form a chemisorbed layer; and supplying the reactive gas into the reaction chamber, wherein at least a portion of the reactive gas reacts with the chemisorbed layer to form a film. The controller may further be configured and programmed to control activating the plasma unit to supply a second plasma discharge in the reaction chamber. Alternatively, the system may further comprise a second plasma unit comprising a second RF power source, and the controller may further be configured and programmed to control activating the second plasma unit to supply a second plasma discharge in the reaction chamber.

In these aspects, in embodiments, the formation of the chemisorbed layer is a self-limiting process. In some embodiments, the formation of the chemisorbed layer is a self-limiting process and the reaction of the reactive gas with the chemisorbed layer is a self-limiting process.

In these aspects, in some embodiments, the first precursor undergoes partial breakdown in the low-power plasma discharge to form the radicalized first precursor.

In these aspects, in some embodiments, the surface of the substrate is contacted with the radicalized first precursor in the substantial absence of charged species.

In these aspects, in some embodiments, the low-power plasma discharge is spatially separated from the surface of the substrate. In some embodiments, the low-power plasma discharge is formed in an upper portion of the reaction chamber, whereas the substrate is located in a lower portion of the reaction chamber. In some embodiments, an ion trap is provided in the reaction chamber between the low-power plasma discharge and the substrate. The ion trap may be an electrically grounded mesh plate. In other embodiments, the low-power plasma discharge is formed in a remote plasma unit.

In these aspects, in some embodiments, the low-power plasma discharge is produced by gas-phase ionization of a gas with a RF power of 100 W or less. In some embodiments, the RF power is 25 W or less.

In these aspects, in some embodiments, the second plasma discharge may be produced by gas-phase ionization of a gas comprising the reactive gas with a second RF power of at least 20 W and less than 1,000 W. In some embodiments, the second RF power is at least 20 W and less than 200 W.

In these aspects, in some embodiments, a temperature of the substrate is at least 40° C. and no more than 450° C. In some embodiments, the temperature of the substrate is at least 100° C. and no more than 400° C.

In these aspects, in some embodiments, the first precursor comprises silicon. In some embodiments, the first precursor comprising silicon may be selected from the group consisting of:

a silane, a halosilane, an aminosilane, a silicon alkoxide, a siloxane, and combinations thereof. In some embodiments, the first precursor comprising silicon may be selected from the group consisting of: dimethylsilane, diethylsilane, trimethylsilane, triethylsilane, dichlorosilane, diiodosilane, hexachlorodisilane, octachlorotrisilane, bis(dimethylamino)silane, bis(dicthylamino)silane, diisopropylaminosilane, N-(diethylaminosilyl)-N-ethylethanamine, hexamethylcyclotrisilazane, tetraethylotrhosilicate, dimethoxydimethylsilane, trimethoxymethylsilane, octamethylcyclotetrasiloxane, 1,1,3,5,5,7-hexamethylcyclotetrasiloxane, 1,3,5,7-tetramethylcyclotetrasiloxane, and combinations thereof.

In these aspects, in some embodiments, the first precursor comprises boron. In some embodiments, the first precursor comprising boron is selected from the group consisting of: a borane, an alkyl borane, an aryl borane, a carborane, an amine borane, an amino borane, a borate ester, a borazine, boron halide, and combinations thereof. In some embodiments, the first precursor comprising boron is selected from the group consisting: of nido-carborane, ortho-carborane, ammonia borane, dimethylamine borane, trimethylamine borane, t-butylamine borane, tris(dimethylamino)borane, B-(cycloriborazanyl)amine borane, trimethyl borate, triethyl borate, borazine, 2,4,6-trichloroborazine, 2,4,6-tribromoborazine, diborazine, and combinations thereof.

In these aspects, in some embodiments, the reactive gas is selected from the group consisting of: an oxygen containing gas, a nitrogen containing gas, a hydrogen containing gas, and combinations thereof. In some embodiments, the reactive gas comprises one or more of oxygen, ozone, water, hydrogen peroxide, an alcohol, nitrogen dioxide, nitrous oxide, oxygen atoms, ammonia, hydrazine, nitric oxide, nitrogen atoms, hydrogen, and hydrogen atoms.

In these aspects, in some embodiments, the film comprises silicon. In some embodiments, the film comprising silicon is selected from the group consisting of: silicon nitride, silicon oxynitride, silicon oxycarbonitride, silicon carbonitride, silicon carbide, silicon oxycarbide, silicon oxide, and combinations thereof. In some embodiments, the film comprising silicon comprises silicon oxycarbonitride, silicon carbonitride, or a combination thereof.

In these aspects, in some embodiments, the film comprises boron. In some embodiments, the film comprising boron is selected from the group consisting of: boron nitride, boron carbide, borocarbonitride, boron oxide, and combinations thereof. In some embodiments, the film comprising boron comprises boron nitride. In some embodiments, the film comprising boron comprises amorphous boron nitride.

### BRIEF DESCRIPTION OF THE DRAWING FIGURES

The accompanying drawings are incorporated into and form a part of the specification to illustrate several examples of the present disclosure. The figures presented herein are not meant to be actual views of any particular material, structure, or device, but are merely idealized representations that are used to describe embodiments of the disclosure. It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure. The drawings, together with the description, explain the principles of the disclosure. The drawings simply illustrate preferred and alternative examples of how the disclosure can be made and used and are not to be construed as limiting the disclosure to only the illustrated and described examples. Further features and advantages will become apparent from the following, more detailed, description of various aspects, embodiments, and configurations of the disclosure, as illustrated by the drawings referenced below.

FIG. 1 is a process diagram of an exemplary embodiment of the disclosure.

FIG. 2 shows representative pulse schemes for the first precursor and reactive gas for two exemplary embodiments of the disclosure. In both cases, the low-power plasma is ignited while introducing the first precursor into the reaction chamber. In the top plot, a plasma is also pulsed while introducing the reactive gas. In this case, the deposition reaction is a radical enhanced process. In the bottom plot, the reactant gas in introduced and the deposition reaction is a thermal process.

FIG. 3 is a schematic presentation of a reactor assembly according to one embodiment of the present disclosure, wherein the low-power plasma discharge is formed in the upper portion of the reaction chamber.

FIG. 4 is a schematic presentation of a reactor assembly according to one embodiment of the present disclosure, wherein the low-power plasma is produced upstream of the reaction chamber using a remote plasma unit (RPU).

FIG. 5(a) and FIG. 5(b), respectively, show the GPC and thickness for the deposition of an SiOC film produced using a TMCTS/O*RE-ALD process using a radicalized TMCTS precursor.

FIG. 6 is a transmission electron microscope (TEM) cross-sectional image of a trench structure coated with a SiOC film using a TMCTS/O*RE-ALD process using a radicalized TMCTS precursor.

FIG. 7(a) and FIG. 7(b), respectively, show the GPC and non-uniformity for an SiO₂ film produced using a SAM-24/O*RE-ALD process at 400° C. using both a radicalized and a non-radicalized (i.e., control) SAM-24 precursors.

### DETAILED DESCRIPTION OF EXEMPLARY EMBODIMENTS

### Definitions.

As used herein, “atomic layer deposition”, abbreviated as “ALD”, refers to a method of depositing a film on a substrate by sequentially exposing its surface to alternate gas-phase reactants. In contrast to chemical vapor deposition, the different reactants are not simultaneously present in the reactor, but rather they are introduced as a series of sequential, non-overlapping pulses. In each of these pulses, the reactant reacts with the surface in a self-limiting way or a substantially self-limiting way. Further, ALD, as used herein, may also be meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of reactants.

As used herein, “boron carbide” or “BₓC_{y}” refers to a material that comprises boron and carbon. In some embodiments, boron carbide may not include significant proportions of elements other than boron and carbon. In some embodiments, the boron carbide comprises B₄C. In some embodiments, the boron carbide may consist essentially of B₄C. In some embodiments, the boron carbide may not include stoichiometric boron carbide. In some cases, the boron carbide can include other elements, such as hydrogen.

As used herein, “boron carbonitride” or “BₓC_{y}N_{z}” refers to a material that that comprises boron, carbon, and nitrogen. Boron carbonitride may be represented by the formula BₓC_{y}N_{z} where the sum of x, y, and z is equal to 3. In some cases, the boron carbonitride may include other elements, such as hydrogen. The boron carbonitride may include boron carbide and boron nitride.

As used herein, “boron nitride” or “BₓN_{y}” refers to a material that that comprises boron and nitrogen. In some embodiments, boron nitride may not include significant proportions of elements other than boron and nitrogen. In some embodiments, the boron nitride comprises BN. In some embodiments, the boron nitride may consist essentially of BN. In some cases, the boron nitride may not include stoichiometric boron nitride. In some cases, the boron nitride can include other elements, such as hydrogen.

As used herein, “boron oxide” or “BₓO_{y}” refers to a material that that comprises boron and oxygen. In some embodiments, boron oxide may not include significant proportions of elements other than boron and oxygen. Boron oxide can be represented by the formula BₓO_{y}, where x can range from about 0 to about 6 and y can range from about 0 to about 3. In some embodiments, the boron oxide comprises B₂O₃. In some embodiments, the boron oxide may consist essentially of B₂O₃. In some cases, the boron oxide may not include stoichiometric boron oxide. In some cases, the boron oxide can include other elements, such as carbon and/or hydrogen.

As used herein, “chemical vapor deposition”, abbreviated as “CVD”, refers to a method of depositing a film on a substrate by exposing its surface to one or more gaseous reactants, which react and/or decompose on the substrate surface to produce a desired film. Typically, CVD is performed by co-introducing the reactants into a reactor.

As used herein, “chemisorption” refers to an adsorption process, caused by a reaction on an exposed surface, which creates, for example, a covalent or ionic bond between the surface and the adsorbate.

As used herein, a “film” refers to a continuous, substantially continuous, or non-continuous material that extends in a direction perpendicular to a thickness direction to cover at least a portion of a surface. A film can include two-dimensional materials, three-dimensional materials, nanoparticles or even partial or full molecular layers or partial or full atomic layers or clusters of atoms and/or molecules. A film may be built up from one or more non-discernable layers (e.g., monolayers or sub-monolayers) to produce a uniform or a substantially uniform material, wherein the number of layers influences the thickness of the material.

As used herein, a “gas” refers to a state of mater consisting of atoms or molecules that have neither a defined volume nor shape. A gas includes vaporized solid and/or liquid and may be constituted by a single gas or a mixture of gases, depending on the context.

As used herein, a “plasma” refers to an ionized gas comprising roughly equal numbers of negatively and positively charged species, generally electrons and ions. Excited and reactive species are also contained within the plasma, such as, for example, atoms and radicals, metastable atoms and molecules, and photons. A plasma discharge requires an externally imposed electric or magnetic field to ionize a gas. Plasma generation schemes and geometries, include, but are not limited to, capacitively coupled plasmas (CCPs), inductively coupled plasmas (ICPs), and RF-hollow cathode (HC) plasmas, which differ in their production of excited and reactive species and, as a result, they can provide very different fluxes of the various species.

As used herein, a “precursor” refers to a compound that participates in a chemical reaction to form another compound or element, wherein a portion of the precursor (an element or group within the precursor) is incorporated into the compound or element that results from the chemical reaction. The compound or element that results from the chemical reaction may be a layer and/or a film that is formed on a surface of a substrate.

As used herein, a “reactant” refers to a compound that participates in a chemical reaction to form another compound or element. In some instances, a reactant is a precursor. In other instances, the compound or element that results from the chemical reaction does not contain a portion of the reactant (an element or group within the reactant) and therefore the reactant is not a precursor.

As used herein, “self-limiting” refers to a process that proceeds by a finite course and that terminates once the finite course is complete. For example, a self-limiting surface reaction terminates when the surface becomes saturated and all of the available and/or accessible surface reactive sites are depleted. At maximum one monolayer may be formed on the surface.

As used herein, “silicon carbide” or “SiC” refers to a material that includes silicon and carbon. In some embodiments, silicon carbide may not include significant proportions of elements other than silicon and carbon. Silicon carbide may be represented by the formula SiC. In some embodiments, the silicon carbide comprises SiC. In some embodiments, the silicon carbide may consist essentially of SiC. Silicon carbide need not necessarily be a stoichiometric composition. An amount of silicon can range from 5% to 50%; an amount of carbon can range from about 50% to about 95%. In some embodiments, SiC films may comprise one or more elements in addition to silicon and carbon, such as hydrogen and/or nitrogen.

As used herein, “silicon carbonitride” or “SiₓC_{y}N_{z}” or “SiCN” refers to a material that comprises silicon, carbon, and nitrogen. Silicon carbonitride may be represented by the formula SiₓC_{y}N_{z}. In some embodiments, the silicon carbonitride may comprise more Si—N bonds than Si—C bonds, for example, a ratio of Si—N bonds to Si—C bonds may be from about 1:10 to about 10:1. In some embodiments, the silicon carbonitride films may comprise from about 0% to about 50% carbon on an atomic basis. In some embodiments, the silicon carbonitride may comprise from about 0.1% to about 40%, from about 0.5% to about 30%, from about 1% to about 30%, or from about 5% to about 20% carbon on an atomic basis. In some embodiments, the silicon carbonitride may comprise from about 0% to about 70% nitrogen on an atomic basis. In some embodiments, the silicon carbonitride may comprise from about 10% to about 70%, from about 15% to about 50%, or from about 20% to about 40% nitrogen on an atomic basis. In some embodiments, the silicon carbonitride may comprise about 0% to about 50% silicon on an atomic basis. In some embodiments, the silicon carbonitride may comprise from about 10% to about 50%, from about 15% to about 40%, or from about 20% to about 35% silicon on an atomic basis. In some cases, the silicon carbonitride may include other elements, such as hydrogen. The silicon carbonitride may include silicon carbide and silicon nitride.

As used herein, “silicon nitride” or “SiₓN_{y}” refers to a material that includes silicon and nitrogen. In some embodiments, silicon nitride may not include significant proportions of elements other than silicon and nitrogen. Silicon nitride may be represented by the formula Si₃N₄. In some embodiments, the silicon nitride comprises Si₃N₄. In some embodiments, the silicon nitride may consist essentially of Si₃N₄. In some cases, the silicon nitride may not include stoichiometric silicon nitride. In some cases, the silicon nitride may include other elements, such as carbon, oxygen, and/or hydrogen.

As used herein, “silicon oxide” or “SiOₓ” refers to a material that includes silicon and oxygen. Silicon oxide can be represented by the formula SiOₓ, where x can be between 0 and 2. In some embodiments, silicon oxide may not include significant proportions of elements other than silicon and oxygen. Silicon oxide may be represented by the formula SiO₂. In some embodiments, the silicon oxide comprises SiO₂. In some embodiments, the silicon oxide may consist essentially of SiO₂. In some cases, the silicon oxide may not include stoichiometric silicon oxide. In some cases, the silicon oxide can include other elements, such as carbon, nitrogen, and/or hydrogen.

As used herein, “silicon oxycarbide” or “Si_{z}OₓC_{y}” or “SiOC” refers to material that comprises silicon, oxygen, and carbon. As used herein, unless stated otherwise, SiOC is not intended to limit, restrict, or define the bonding or chemical state, for example, the oxidation state of any of Si, O, C, and/or any other element in the film. In some embodiments, the Si_{z}OₓC_{y} may comprise Si—C bonds and/or Si—O bonds. In some embodiments, the SiOC may comprise Si—C bonds and Si—O bonds and may not comprise Si—N bonds. In some embodiments, the SiOC may comprise Si—H bonds in addition to Si—C and/or Si—O bonds. In some embodiments, the SiOC may comprise more Si—O bonds than Si—C bonds, for example, a ratio of Si—O bonds to Si—C bonds may be from about 1:10 to about 10:1. In some embodiments, the SiOC may comprise from about 0% to about 50% carbon on an atomic basis. In some embodiments, the SiOC may comprise from about 0.1% to about 40%, from about 0.5% to about 30%, from about 1% to about 30%, or from about 5% to about 20% carbon on an atomic basis. In some embodiments, the SiOC may comprise from about 0% to about 70% oxygen on an atomic basis. In some embodiments, the SiOC may comprise from about 10% to about 70%, from about 15% to about 50%, or from about 20% to about 40% oxygen on an atomic basis. In some embodiments, the SiOC may comprise about 0% to about 50% silicon on an atomic basis. In some embodiments, the SiOC films may comprise from about 10% to about 50%, from about 15% to about 40%, or from about 20% to about 35% silicon on an atomic basis. In some embodiments, silicon oxycarbide can be represented by the chemical formula Si_{z}OₓC_{y}, where z can range from about 0 to about 2, x can range from about 0 to about 2, and y can range from about 0 to about 5.

As used herein, “silicon oxycarbonitride” or “Si_{z}OₓC_{y}N_{w}” or “SiOCN” refers to material that comprises silicon, oxygen, nitrogen, and carbon. As used herein, unless stated otherwise, SiOCN is not intended to limit, restrict, or define the bonding or chemical state, for example, the oxidation state of any of Si, O, C, N and/or any other element in the material. In some embodiments, SiOCN is material that can be represented by the chemical formula Si_{z}OₓC_{y}N_{w}, where z can range from about 0 to about 2, x can range from about 0 to about 2, y can range from about 0 to about 2, and w can range from about 0 to about 2.

As used herein, “silicon oxynitride” or “SiOₓN_{y}” refers to a material that includes silicon, oxygen, and nitrogen. As used herein, unless stated otherwise, SiOₓN_{y} is not intended to limit, restrict, or define the bonding or chemical state, for example, the oxidation state of any of Si, O, N and/or any other element in the material. In some embodiments, SiOₓN_{y} is material that can be represented by the chemical formula SiOₓN_{y}, where x can range from about 0 to about 2, y can range from about 0 to about 2. The silicon oxynitride may include silicon oxide and silicon nitride.

As used herein, a “substrate” refers to an underlying material or materials that may be used to form, or upon which, a device, a circuit, material, or material layer may be formed. The substrate may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide. A substrate can include one or more layers overlying a bulk material, for example the substrate may include nitrides, for example TiN, oxides, insulating materials, dielectric materials, conductive materials, metals, such as tungsten, ruthenium, molybdenum, cobalt, aluminum or copper, or metallic materials, crystalline materials, epitaxial, heteroepitaxial, and/or single crystal materials. The substrate can include various topologies, such as gaps, including recesses, lines, trenches, or spaces between elevated portions, such as fins, and the like formed within or on at least a portion of a layer of the substrate.

As used herein, a “substituent” refers to an atom or a group of atoms that replaces one or more atoms (such as a hydrogen atom) or groups of atoms in a parent compound, thereby resulting in a new compound. The substituent is substituted for the original atom or a group of atoms in the parent molecule. For simplicity, a substituent may be indicated in a chemical formula as an “R” group and each “R” group in a compound may be independently selected unless otherwise specifically indicated that this is not the case. Examples of substituent groups include, but are not limited to: a hydrogen atom (H); an “alkyl group”, such as a saturated linear or branched C₁ to C₁₀ hydrocarbons, preferably C₁ to C₆ hydrocarbons (e.g., methyl, ethyl, propyl, iso-propyl, butyl, i-butyl, s-butyl, t-butyl, pentyl, 3-pentyl, neo-pentyl, and hexyl); a “cycloalkyl group”, such as C₃ to C₆ cyclic hydrocarbons (e.g., cyclopropyl, cyclobutyl, cyclopentyl, and cyclohexyl); an “alkenyl group”, such as C₂ to C₆ linear or branched unsaturated hydrocarbons (e.g., vinyl, allyl, propenyl, butenyl, pentenyl, hexenyl, butadienyl, pentadienyl, hexadienyl, ethynyl, propargyl, butynyl, pentynyl, and hexynyl); an “aryl group”, such as a phenyl, benzyl, tolyl, xylyl, naphthyl, cyclopentadienyl, and methyl, dimethyl, or ethyl cyclopentadienyl groups; a hydroxy group (OH); an “alkoxy group”, such as a linear or branched C₁ to C₁₀ alkoxy group, typically a C₁ to C₄ alkoxy group (e.g., methoxy, ethoxy, n-propoxy, i-propoxy, butoxy, iso-butoxy, see-butoxy, and tert-butoxy); a hydroxyalkyl group such as a linear or branched a C₁ to C₁₀ hydroxyalkyl, typically a linear or branched C₁ to C₄ hydroxyalkyl (e.g., hydroxymethyl, hydroxyethyl, hydroxypropyl, hydroxybutyl, hydroxypentyl, and hydroxyhexyl); an “alkoxycarbonyl group”, such as a linear or branched C₁ to C₆ carbonyl hydrocarbon (e.g., methoxycarbonyl, ethoxycarbonyl, propoxycarbonyl, isopropoxycarbonyl, butoxycarbonyl, pentoxycarbonyl, and hexyloxycarbonyl); a thiol group (SH); an “alkylthiol group”, such as a linear or branched C₁ to C₆ thiols (e.g., thiolmethyl, thiolethyl, thiolpropyl, thiolbutyl, thiolpentyl, and thiolhexyl); a halide (X), such as fluoride (F), chloride (Cl), bromide (Br), and iodide (I); and an “haloalkyl group”, such as a linear or branched C₁ to C₆ alkylhalides having one or more halogen atoms (e.g., iodomethyl, bromomethyl, chloromethyl, fluoromethyl, trifluoromethyl, 2-chlorocthyl, 2-fluorocthyl, 2,2,2-trifluoroethyl, and pentafluoroethyl). A substituent group may, in and of itself, be substituted. For example, a hydroxyalkyl group is a substituted alkyl group, where a H atom on the alkyl group is replaced with an OH group.

Articles “a” or “an” refer to a species or a genus including multiple species, depending on the context. As such, the terms “a/an”, “one or more” and “at least one” can be used interchangeably herein. It is also to be noted that the terms “comprising”, “including”, and “having” can be used interchangeably.

The term “about” generally refers to a range of numbers that is considered equivalent to the recited value (e.g., having the same function or result). In some instances, the term about may include numbers that are rounded to the nearest significant figure.

The term “essentially” as applied to a composition, a method, or a system generally means that the additional components do not substantially modify the properties and/or function of the composition, the method, or the system.

The term “substantially” as applied to a composition, a method, or a system generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁—Xₙ, Y₁—Yₘ, and Z₁—Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

It should be understood that every numerical range given throughout this disclosure is deemed to include the upper and the lower end points, and each and every narrower numerical range that falls within such broader numerical range, as if such narrower numerical ranges were all expressly written herein. By way of example, the phrase “from about 2 to about 4” or “from 2 to 4” includes 2 and 4 and the whole number and/or integer ranges from about 2 to about 3, from about 3 to about 4 and each possible range based on real (e.g., irrational and/or rational) numbers, such as from about 2.1 to about 3.9, from about 2.1 to about 3.4, and so on.

The present disclosure generally relates to methods of forming a film on the surface of a substrate using plasma enhanced atomic-layer deposition (PE-ALD) and systems for performing such methods, and in particular to the use of a low-power plasma to affect partial breakdown of chemical precursors to enhance their reactivity. More specifically, the present disclosure generally relates to methods of forming a film on the surface of a substrate using radical-enhanced atomic-layer deposition (RE-ALD) and systems for performing such methods, and in particular to the use of a low-power plasma to affect partial breakdown of chemical precursors to enhance their reactivity. Various aspects of the methods and systems and the benefits derived therefrom will now be described.

Finding improved chemical precursors for ALD processes is an ongoing effort, as increasingly stringent material and process requirements need to be met in order to enable improvement of semiconductor devices. In general, precursors are sought that are readily volatilizable and transportable to the deposition location, at temperatures consistent with fabrication of device structures. Desirable precursors may produce highly conformal films on the substrate with which the precursor vapor is contacted, without the occurrence of decomposition reactions that would adversely impact the product device structure. A typical way to work with relatively unreactive chemicals is to utilize plasma processing, but this has its own disadvantages (e.g., plasma induced damage, anisotropy) and the options are limited if the precursor is too unreactive to even chemisorb on the substrate surface. In this regard, disclosed herein are methods and systems for depositing a film on a surface of a substrate using a low-power plasma to partially breakdown precursors to increase their reactivity. The methods and systems disclosed herein advantageously expand the selection of precursors and allow for the use of relatively “non-reactive” precursors that may not readily chemisorb on a substrate surface and/or participate in thermal ALD reactions. The disclosed methods can improve film growth rates, allow for lower-temperature processing, and improve the uniformity and conformality of the film, while minimizing the negative effects typically associated with plasma-processing. These and other advantages will be apparent from the disclosure of the various aspects, embodiments, and configurations contained herein.

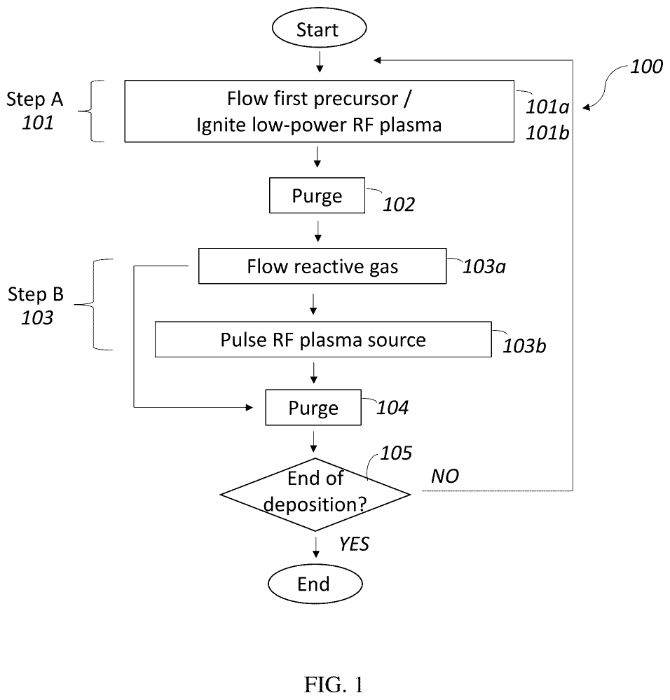

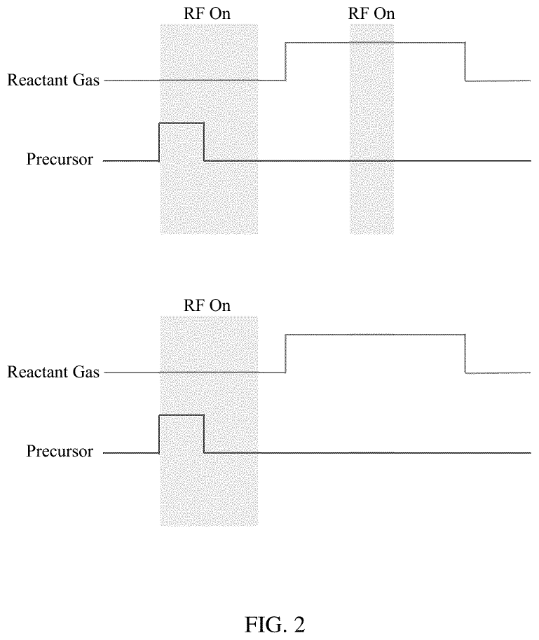

An aspect of the present disclosure are methods of depositing a film on the surface of a substrate that is contained in a reaction chamber using ALD. FIG. 1 is a process flow diagram 100 of an embodiment of the disclosure. In 101, a remote low-power plasma is used to partially breakdown at least a portion of a first precursor to form activated radical species (referred to as a radical or radicalized first precursor). The first precursor is introduced 101a and the low-power plasma is ignited 101b. The radicalized first precursor is more reactive than the first precursor which it is derived from, and it is able to more efficiency chemisorb on the surface of the substrate (or on another layer present on the surface of the substrate) forming maximally one monolayer or sub-monolayer thereon. In some embodiments, due to the remoteness of the low-power plasma, contacting the surface of the substrate with the radicalized first precursor occurs in the substantial absence of charged species (e.g., ions and/or electrons). Next, in 103, a reactive gas is introduced into the reaction chamber 103a to react with the chemisorbed layer on the substrate to form a film. The reactive gas may also be activated and/or radicalized using a second plasma, wherein the plasma is pulsed 103b and radicals and/or excited species contained within the plasma react with the first radicalized precursor layer in a plasma-enhanced process (103a and 103b). Alternatively, the reactive gas may react with the chemisorbed layer in a thermally driven process (only 103a). Examples of reactant/plasma pulse sequences are shown in FIG. 2. In the top plot the plasma is pulsed in both reaction steps; whereas in the bottom plot the plasma is pulsed in the first step only and the second step is a thermal process. Referring to FIG. 1, blocks 101 and 103 may each be referred to as a half cycle and together they define a cycle, each half-cycle being sequentially repeated to grow the film. The reaction chamber may be optionally purged in between each of the two half cycles and/or after a cycle, as shown in blocks 102 and 104. Once the targeted film thickness has been reached, the process is terminated. The method and the individual process steps will be described in more detail below.

In the methods disclosed herein, a low-power plasma, that is formed remotely in a location that is spatially separated from the substrate (i.e., a remote plasma), is used to partially breakdown at least a portion of the first precursor to produce a radicalized first precursor (101 in FIG. 1). The radicalized precursor is more reactive that the precursor from which it is derived, and this increases the rate of the chemisorption on the substrate surface. In this context, the term “breakdown” refers to the process or effect of dissociating, fragmenting, or decomposing a chemical entity (in this case the precursor) into fragments; whereas “partial breakdown” means that the precursor is broken down, but at least a portion of the molecular structure of the precursor remains substantially intact in the resulting radicalized precursor. Additionally, or alternatively, “partial breakdown” means that the precursor is broken down, but not to the extent that bimolecular and/or non-self-limited type adsorption occurs on the substrate surface; rather the radicalized precursor chemisorbs on the substrate surface via a self-limited process. Generally, in traditional PE-ALD processes, plasma-enhancement (i.e., generating plasma) is only performed on the subsequent deposition step (i.e., the second half cycle), as plasma-enhancement during the chemisorption step (i.e., the first half cycle) can lead to CVD type reactions (e.g., bimolecular, non-self-limited reactions) on the surface. However, the inventors of the present disclosure have unexpectedly found that by carefully selecting and/or controlling the plasma conditions, the reactivity of the precursor can be increased through partial-breakdown, and self-limiting ALD type adsorption can be maintained.

The remote low-power plasma is produced by gas-phase ionization of a gas using a radio frequency (RF) (e.g., 13.56 MHz or 27 MHZ) plasma generator. A number of plasma discharge/reactor configurations may be employed to provide the remote low-power plasma. For instance, in some embodiments, the low-power plasma discharge may be provided in the upper part of the reaction chamber wherein an ion trap separates the plasma in a “plasma zone” from the lower part of the reaction chamber where the substrate is located (the “reaction zone”). In other embodiments, a low-power plasma discharge may be provided upstream of the reaction chamber using a remote plasma unit (RPU). A common feature in these configurations is the physical separation of the plasma from the substrate, which reduces, and may even eliminate, unwanted interactions of certain plasma species (e.g., electrons, ions, and photons) with the substrate surface. Because of the remoteness of the plasma, ions and electrons are lost due to collisions with other energetic species in the plasma and with the surfaces of the reaction chamber, ion trap, and/or conduit piping. Radicals are also lost; however, they are lost at a lower rate and a portion of the radicalized first precursor reaches the substrate and chemisorbs to form a monolayer or sub-monolayer on the surface of the substrate.

The RF power for generating the low-power plasma can be varied in different embodiments of the current disclosure. As will be appreciated, the power for generating the low-power plasma, and hence the ionization energy of the plasma, may vary based on the type of precursor and may be tuned to affect the degree of dissociation of the precursor and the chemisorption onto the substrate surface. The RF power should be set high enough to form activated radical species based on the precursor but low enough such that the breakdown is insufficient to cause CVD-type film deposition. Typically, the RF power for generating the low-power plasma is maintained at about 100 W or less, typically at about 50 W or less, or more typically at about 25 W or less. (In comparison, the RF power for traditional PE-ALD processes is much higher, typically between 100-1,000 W). At such low RF powers, the low-power plasma may be characterized as having a low degree of ionization and a low electron density. In some embodiments, the RF power for generating the low-power plasma is maintained at about 100 W or less, typically from about 0.1 W to about 100 W, more typically from about 1 W to about 100 W, more typically from about 1 W to about 90 W, more typically from about 1 W to about 80 W, more typically from about 1 W to about 70 W, more typically from about 1 W to about 60 W, more typically from about 1 W to about 50 W, more typically from about 1 W to about 40 W, more typically from about 1 W to about 30 W, more typically from about 1 W to about 20 W, more typically from about 1 W to about 10 W, more typically from about 5 W to about 100 W, more typically from about 5 W to about 90 W, more typically from about 5 W to about 80 W, more typically from about 5 W to about 70 W, more typically from about 5 W to about 60 W, more typically from about 5 W to about 50 W, more typically from about 5 W to about 40 W, more typically from about 5 W to about 30 W, more typically from about 5 W to about 20 W, more typically from about 10 W to about 100 W, more typically from about 10 W to about 90 W, more typically from about 10 W to about 80 W, more typically from about 10 W to about 70 W, more typically from about 10 W to about 60 W, more typically from about 10 W to about 50 W, more typically from about 10 W to about 40 W, more typically from about 10 W to about 30 W, or any intermediate range of powers between about 0.1 W and about 100 W. In some embodiments, the RF power may be maintained at about 100 W or less, at about 90 W or less, at about 80 W or less, at about 70 W or less, at about 60 W or less, at about 50 W or less, at about 40 W or less, at about 30 W or less, at about 25 W or less, at about 20 W or less, at about 15 W or less, or at about 10 W or less. In some embodiments, the RF power may be maintained at about 1 W, at about 5 W, at about 10 W, at about 20 W, at about 25 W, at about 30 W, at about 40 W, at about 50 W, at about 60 W, at about 70 W, at about 80 W, at about 90 W, or at about 100 W.

The first precursor is provided to the low-power plasma discharge and the reaction chamber by way of a carrier gas (inert gas). The precursor is dosed or pulsed into a continuous flow of the carrier gas. In some embodiments, the carrier gas may be the feed gas for the plasma discharge. In some embodiments, the low-power plasma is generated from a gas containing substantially only a noble gas. In some embodiments, the plasma is generated from a noble gas. The noble gas may be selected from a group consisting of helium (He), neon (Ne), argon (Ar), krypton (Kr), xenon (Xe), and mixtures thereof. The carrier gas may help to excite and partially breakdown the precursor when RF power is applied, but it does not chemically react with the precursor. In other embodiments, one or more additives, may be introduced either with the precursor or separately from the precursor. The low-power plasma is ignited by pulsing the RF power. The duration of the RF power pulse should at least partially overlap with the duration of the precursor pulse. The relative timing of the low-power plasma and precursor pulses may be used to tune the degree of precursor breakdown and radicalization. In some embodiments, the RF power and the precursor pulse are initiated simultaneously. In some embodiments, the RF power is initiated later than the precursor pulse. In some embodiments, the precursor pulse is initiated later than the RF power. In some embodiments, the RF power and the precursor are simultaneously pulsed such that the duration of the two pulses overlaps (e.g., see FIG. 2). In other embodiments, the duration of the RF power pulse is longer than the duration of the precursor pulse. Since the chemisorption step is a self-limiting or substantially self-limiting process, the number of deposited precursor molecules is determined by or predominantly determined by the number of accessible reactive sites on the surface and is independent of the exposure time after saturation of the surface. Excess precursor may be supplied to the reaction chamber, and the duration of the precursor and plasma pulses should be sufficiently long such that the surface becomes saturated. Typical plasma/precursor pulse times range from about 0.1 second up to about 10 seconds, preferably from about 1 second to about 5 seconds, after which the reaction chamber may be flushed or purged to remove unreacted precursor, gaseous reaction by-products, and other species.

Next, a reactant such as a reactive gas is introduced into the reaction chamber (103 in FIG. 1). In some embodiments, the reactive gas is entrained in or pulsed into a continuous flow of the carrier gas into the reaction chamber. In other embodiments, the deposition reaction is carried out in a separate reaction chamber than where the first chemisorption reaction is performed. In some embodiments, the reactive gas is a precursor (and may be referred to as the second precursor) meaning that a portion of the reactive gas (an element or group within the reactive gas) is incorporated into resultant film. For example, the reactive species may react with the chemisorbed layer via an exchange reaction or an addition reaction. In other embodiment, the reactive gas may chemically modify the chemisorbed layer, for example, by an elimination reaction or by oxidation or reduction to form a film, but no element or groups within the reactive species is incorporated into the resultant film. The choice of the reactive gas will depend upon the composition of the chemisorbed layer and the desired film. In some embodiments, the deposition reaction may proceed via a thermal process (only 103a), whereby the reactive gas thermally reacts with the chemisorbed layer on the substrate surface. In other embodiments, the deposition reaction may proceed via a plasma-enhanced process (103a and 103b), whereby the reactive gas comprises excited species and/or radicals which react with the chemisorbed layer. As with the adsorption step, the deposition step is also a self-limiting or substantially self-limiting process, determined by the number of deposited precursor molecules on the surface and is independent of the exposure time after saturation. Excess of the reactive gas may be provided and the duration of the reactive gas pulse should be sufficiently long such that the chemisorbed layer is substantially or completely transformed into the target layer. Typical exposure or pulse times range from about 0.1 second up to about 10 seconds, preferably from about 1 second to about 5 seconds, after which the reaction chamber is flushed or purged to remove any unreacted reactive gas, gaseous reaction by-products, and other species.

In embodiments where the deposition reaction proceeds via a PE-ALD process (103a and 103b), the plasma (which may be referred to as a “second plasma”) is supplied using a radio frequency (RF) (e.g., 13.56 MHz or 27 MHz) plasma generator. The reactive gas comprises one or more excited and/or radical species that may be formed in situ in the reaction chamber using a direct plasma formed near the vicinity or directly above the substrate. Generally, use of a direct plasma results in a higher density of plasma species (e.g., ions, electrons, radicals, and other excited species) near the substrate and those species may interact with the substrate and influence the film growth and quality. Alternatively, the reactive gas comprising one or more excited and/or radical species may be formed in situ in the reaction chamber using a remote plasma that is formed in a location that is spatially separated from the substrate, or it may be formed in a plasma upstream of the reaction chamber using a remote plasma unit (RPU) or the like. The second plasma may be formed using a feed gas comprising a carrier gas (inert gas), a reactive gas, or a mixture of gasses. The feed gas is fed into the reaction chamber and the plasma is pulsed. In some embodiments, the plasma is generated from a feed gas comprising a reactive gas which may optionally be mixed or co-fed with a carrier gas. In other embodiments, the plasma is generated from a reactive gas. The reactive gas may be, by way of non-limiting example, oxygen (O₂), nitrogen (N₂), ammonia (NH₃), hydrogen (H₂), and mixtures thereof. The carrier gas may be a noble gas selected from the group consisting of helium (He), neon (Ne), argon (Ar), krypton (Kr), xenon (Xe), and mixtures thereof. The excited species from noble gases in the plasma do not necessarily contribute material to the deposited film but can, in some circumstances, contribute to film growth as well as help in the formation and ignition of the plasma. In some embodiments, the feed gas comprises oxygen. In some embodiments, the feed gas comprises nitrogen. In some embodiments, the feed gas comprises ammonia. In some embodiments, the feed gas comprises hydrogen. In some embodiments, the feed gas comprises nitrogen and hydrogen. In some embodiments, the feed gas comprises an oxygen containing compound that forms O* atoms in the plasma. In some embodiments, the feed gas comprises a nitrogen containing compound that forms N* atoms in the plasma. In some embodiments, the feed gas comprises a hydrogen containing compound that forms H* atoms in the plasma.

The RF power for generating the second plasma can be varied in different embodiments of the current disclosure. In some embodiments, the power for generating the second plasma is typically from about 10 W to about 1,500 W, more typically from about 20 W to about 1,000 W, more typically from about 20 W to about 900 W, more typically from about 20 W to about 800 W, more typically from about 20 W to about 700 W, more typically from about 20 W to about 600 W, more typically from about 20 W to about 500 W, more typically from about 20 W to about 400 W, more typically from about 20 W to about 300 W, more typically from about 20 W to about 200 W, more typically from about 20 W to about 100 W, or any intermediate range of powers between about 10 W and about 1,500 W. In some embodiments, the RF power for generating the second plasma may be maintained at about 20 W, at about 30 W, at about 40 W, at about 50 W, at about 60 W, at about 70 W, at about 80 W, at about 90 W, at about 100 W, at about 120 W, at about 140 W, at about 160 W, at about 180 W, at about 200 W, at about 220 W, at about 240 W, at about 260 W, at about 280 W, at about 300 W, at about 320 W, at about 340 W, at about 360 W, at about 380 W, at about 400 W, at about 420 W, at about 440 W, at about 460 W, at about 480 W, at about 500 W, at about 520 W, at about 540 W, at about 560 W, at about 580 W, at about 600 W, at about 620 W, at about 640 W, at about 660 W, at about 680 W, at about 700 W, at about 720 W, at about 740 W, at about 760 W, at about 780 W, at about 800 W, at about 820 W, at about 840 W, at about 860 W, at about 880 W, at about 900 W, at about 920 W, at about 940 W, at about 960 W, at about 980 W, or at about 1,000 W. Adjusting the power of the plasma generator can affect the amount/density and energy of reactive species generated by plasma. Without limiting the disclosed method to any specific theory, higher power may lead to the generation of higher energy ions and radicals. This may affect the degree of damage that the reactive species may cause on the surfaces of the substrate.

In some embodiments, the method further comprises purging the reaction chamber between the two half cycles and/or after a cycle (FIGS. 1, 102 and/or 104) or periodically to remove unreacted reactants (e.g., precursors and reactive gases) and gas-phase reaction by-products from the surface of the substrate. Purging may be affected, for example, by evacuating the reaction chamber with a vacuum pump and/or by replacing the gas inside a reaction chamber with an inert or substantially inert gas such as argon or nitrogen. In some instances, a purging step may be implemented between two pulses of gases which react with each other or, in other instances, purging may be implemented between two pulses of gases that do not react with each other. Purging may avoid, or at least reduce, gas-phase interactions between two gases reacting with each other. It shall be understood that a purge can be affected either in time or in space, or both. For example, in the case of temporal purges, a purge step can be used in the temporal sequence of providing a first precursor to a reaction chamber, providing a purge gas to the reaction chamber, and then providing a reactive gas to the reaction chamber, wherein the substrate on which a material is deposited does not move. For example, in the case of spatial purges, a purge step can involve moving a substrate from a first location to which a first precursor is continually supplied, through a purge gas curtain, to a second location to which a reactive gas is continually supplied.

The various steps shown in FIG. 1 may be repeated one or more times to grow a film of a desired thickness on the substrate surface. For example, in some embodiments, the method comprises repeating steps 101 and 103 one or more times to form a film of a desired thickness on the substrate surface. In some embodiments, the method comprises repeating steps 101, 102, 103, and 104 one or more time to form a film of a desired thickness on the substrate surface. In other embodiments, the method comprises repeating steps 101, 102, and 103 or repeating steps 101, 103, and 104 one or more time to form a film of a desired thickness on the substrate surface. Other steps may be inserted in the process as needed. For example, other reaction or activation steps may be performed, and/or cleaning steps may be performed between the various steps (101, 102, 103, and/or 104). In other embodiments, the method consists essentially of repeating steps 101, 102, 103, and 104 one or more time to form a film of a desired thickness on the substrate surface, wherein the method does not include other reaction or activation steps. In yet other embodiments, the method consists of repeating steps 101, 102, 103, and 104 one or more time to form a film of a desired thickness on the substrate surface. The number of repeated cycles (n) is not particularly limited and may be between 1 and about 5,000. In some embodiments, the number of repeated cycles (n) is typically between 1 and about 2,000, between 1 and about 1,000, between 1 and about 500, between 1 and about 200, between 1 and about 100, or more typically between about 10 and about 1,000, more typically between about 10 and about 500, more typically between about 10 and about 200, more typically between about 10 and about 100, or even more typically between about 50 and about 1,000, even more typically between about 50 and about 500, or even more typically between about 50 and about 200. The number of repetitions of the deposition cycle (n) depends on the growth per-cycle (GPC) rate of the deposited material and the desired thickness of the film.

As will be appreciated by one of skill in the art, a number of process parameters may impact the growth rate of the film and the quality the film (e.g., uniformity, conformality, and electrical properties). These process parameters include, but are not limited to, the temperature of the substrate and gasses that are introduced into the reaction chamber, the pressure of the reaction chamber, the duration of the purge steps (if any), the plasma power and the pulse duration of the low-power plasma and second plasma (if any), and the purity of the precursors, reactants, and other gasses. Optimization of these parameters to obtained improved growth rates and film properties can be achieved based on routine work and such optimization is within the capabilities of one of skill in the art.

The methods according to the current disclosure may be performed at an elevated temperature. For instance, the substrate may be maintained at an elevated temperature. In some embodiments, the substrate may be maintained at a first temperature and the reaction chamber walls may be maintained at a second temperature. The temperature of the substrate may be optimized to tune or maximize the deposition process on the substrate surface, whereas the reactor wall temperature may be selected to minimize deposition on the chamber walls. In some embodiments, the substrate may be maintained at a first temperature and the reaction chamber walls maintained at a second temperature. In some embodiments, the deposition process may be performed by maintaining the substrate temperature from about 40° C. to about 600° C., typically from about 75° C. to about 500° C., more typically from about 75° C. to about 450° C., more typically from about 75° C. to about 425° C., more typically from about 75° C. to about 400° C., more typically from about 100° C. to about 450° C., more typically from about 100° C. to about 425° C., more typically from about 100° C. to about 400° C., more typically from about 100° C. to about 375° C., more typically from about 100° C. to about 350° C., more typically from about 100° C. to about 325° C. or more typically from about 100° C. to about 300° C. In some embodiments, the deposition process may be performed by maintaining the substrate temperature at about 50° C., at about 75° C., at about 100° C., at about 125° C., at about 150° C., at about 175° C., at about 200° C., at about 225° C., at about 250° C., at about 275° C., at about 300° C., at about 325° C., at about 350° C., at about 375° C., at about 400° C., at about 425° C., at about 450° C., at about 475° C., at about 500° C., at about 525° C., at about 550° C., at about 575° C., or at about 600° C. In other embodiments, the deposition process may be performed at ambient temperature. In some embodiments, ambient temperature is room temperature (RT). In some embodiments, ambient temperature may vary between about 20° C. and about 30° C.

The methods according to the current disclosure may be performed at reduced pressure. In some embodiments, the pressure within the reaction chamber during the deposition process is less than about 500 Torr, typically from about 0.1 Torr to about 500 Torr, or more typically from about 0.5 Torr to about 100 Torr, or even more typically from about 1 Torr to about 20 Torr. In some embodiments, the pressure within the reaction chamber during the deposition process is less than about 100 Torr, less than about 50 Torr, less than about 20 Torr, or less than about 10 Torr. In some embodiments, the pressure during a deposition cycle is lower than about 20 Torr. In some embodiments, the pressure during a deposition cycle is lower than about 10 Torr. In some embodiments, the pressure during a deposition cycle is higher than about 1 Torr. In some embodiments, the pressure during a deposition cycle is higher than about 5 Torr. In some embodiments, the pressure during a deposition cycle is between about 1 Torr and about 25 Torr. In some embodiments, the process may be performed in constant pressure. In some embodiments, the pressure in the reaction chamber during the first half cycle is different than the pressure inside the reaction chamber during the second half cycle. For example, a first pressure in the reaction chamber during the first half cycle may be higher than a second pressure in the reaction chamber during the second half cycle. Alternatively, a first pressure in the reaction chamber during the first half cycle may be lower than a second pressure in the reaction chamber during the second half cycle. In other instances, a first pressure within the reaction chamber during the first half cycle may be the same or substantially the same as second pressure in the reaction chamber during the second half cycle. Without limiting the disclosed method to any specific theory, in some embodiments, increasing the process pressure may increase the film growth rate and improve the film properties, thus reducing the necessary cycle time/number to obtain the desired film properties and film thickness. These improvements can be attributed to changes in the surface saturation level, the enhancement of precursor diffusion, as well as the higher probability for surface reactions to occur at the active sites.

Another aspect of the disclosure is a semiconductor processing apparatus or systems for depositing a film on a surface of a substrate using the methods described herein. The apparatus comprises at least one reaction chamber for accommodating a substrate; in some embodiments the apparatus may have one reaction chamber, two reaction chambers, three reaction chambers, four reaction chambers, or more. The apparatus further comprises a means for forming a radicalized first precursor from a first precursor using a low-power plasma discharge and a means for sequentially exposing the substrate to the radicalized first precursor and a reactive gas.

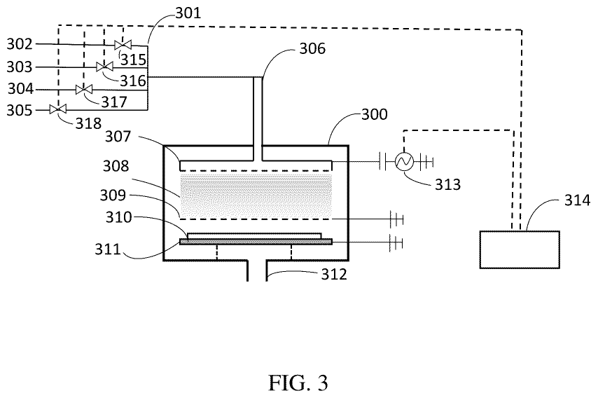

FIG. 3 shows an example of an embodiment of an apparatus where the low-power plasma is formed in the upper portion of the reaction chamber 300. A carrier gas is supplied from a first carrier gas source 302 through a gas manifold 301 into the reaction chamber 300. The carrier gas flows through a showerhead 307 that is positioned directly above a susceptor 311 on which a wafer (i.e., a planar substrate) 310 is placed. A first precursor is also supplied from a first source 303, in the form of a gas, through the gas manifold 301 into the reaction chamber through the showerhead 307. The first precursor many be vaporized and entrained in or pulsed into the carrier gas. The apparatus is also configured to allow for the introduction of other gasses, such as the reactive gas and other gasses (e.g., other precursors or reactive gasses, carrier, dilutant, process, feed, and/or purging gasses), either through the shower head 307 or from other ports (not shown) into the reaction chamber. Thus, the apparatus may comprise second and third sources, 304 and 305. Unreacted gasses and gaseous reaction by-products exit the reaction chamber through an exhaust line 312. The reaction chamber 300 may optionally be equipped with a purge line and/or a pump line coupled to a vacuum pump so that the reaction chamber may be purged between the various reaction cycles (not shown). An RF power source 313 is electrically connected to the showerhead 307, allowing for the showerhead to be biased relative to the susceptor 311, to form a plasma discharge between the two. Optionally, an ion trap 309 may be positioned between the showerhead 307 and the wafer 310 to restrict the plasma zone 308 to upper portion of the chamber, above the ion trap. For example, an electrically grounded mesh plate may be used as an ion trap. In some embodiments, the mesh plate is a metal plate comprising hundreds of holes in a showerhead-like pattern that lets radical species pass through to the wafer 310 while trapping the ions. For instance, the mesh plate may comprise between about 1,000 to about 5,000 holes, each hole having a diameter between about 0.5 mm to about 2 mm. The addition of the ion trap, beneficially reduces or even eliminates interactions of electrons and ions with the wafer surface by restricting the plasma to the plasma zone 308 in the upper portion of the reaction chamber 300. The apparatus also comprises a controller 314 operably connected to the first, second, third, and fourth gas valves, 315-318, the RF power source 313, and other components (not shown).

The controller 314 is configured and programmed to independently control (e.g., turn on and off, etc.) the supply of the various gasses (e.g., carrier gas, first precursor, reactive gas, and any dilutant, process, feed, and/or purging gasses etc.) and the RF power source 313, as required, to deposit a film on the surface of the wafer 310. In some embodiments, the controller 314 is configured to open valve 315 to flow the carrier gas from the first carrier gas source 302 into the reaction chamber. It is further configured to open valve 316 to flow the first precursor from the first source 303 into the reaction chamber and to turn on the RF power source 313 to form the low-power plasma. Turning on the RF power 313 and opening valve 316 may be done one after the other, or simultaneously. After a set period of time, the controller 314 closes the valve to the first precursor 316 and turns off the RF power source 313. Next, the controller 314 opens valve 317 to flow the reactive gas from the second source 304 into the reaction chamber. After a set period of time, the controller 314 closes the valve 317 to the reactive gas 304. The controller 314 is programed to repeat the various process steps to grow a film on the surface of the wafer 310. The controller 314 may be programed to perform other process steps in between these various steps.

In another embodiment, the controller 314 is configured to open valve 315 to flow the carrier gas from the first carrier gas source 302 into the reaction chamber, then open valve 316 to flow the first precursor from the first source 303 into the reaction chamber while turning on the RF power source 313 to form the low-power plasma. Turning on the RF power 313 and opening valve 316 may be done one after the other, or simultaneously. After a set period of time, the controller 314 closes the valve to the first precursor 316 and turns off the RF power source 313. Next, the controller 314 opens valve 317 to flow the reactive gas from the second source 304 into the reaction chamber and, after a set period of time, pulses (turn on, then off) the RF power source 313. After another set period of time, the controller 314 closes the valve 317 to the reactive gas 304. The controller 314 is programed to repeat the various process steps to grow a film on the surface of the wafer 310. The controller 314 may be programed to perform other process steps in between these various steps.

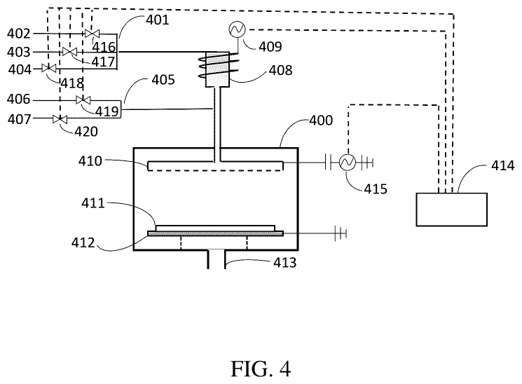

FIG. 4 shows an example of an embodiment of an apparatus where the low-power plasma is formed using a remote plasma unit (RPU) 408 upstream of the reaction chamber 400. Optionally, a second plasma source may be provided. For example, the second plasma source 415 may be electrically connected to a showerhead 410, allowing for the showerhead to be biased relative to the susceptor 412 to form a second plasma discharge between the two. A carrier gas is supplied from a first carrier gas source 402 through a gas manifold 401 and passed through the RPU 408 into the reaction chamber 400 through the showerhead 410 that is positioned directly above a susceptor 412 on which a wafer 411 is placed. A first precursor from a first source 403 may also be supplied through the gas manifold 401 and passed through the RPU unit 408 and through the showerhead 410. The first precursor may be vaporized and entrained in or pulsed into the carrier gas. The apparatus is also configured to allow for the flow of other gasses from an optional third source 404 through the RPU 408. For example, in some instances, it may be beneficial to introduce a cleaning gas (e.g., NF₃ diluted in an inert gas) periodically or even between every reaction cycle to remove any deposition from decomposed precursor chemicals in one or more of the gas lines, the gas manifold 401, RPU 408, and the showerhead 410. Additional gasses, such as a reactive gas from a second source 406 and optional other gasses (e.g., carrier, dilutant, process, feed, and/or purge gasses), may flow from a second gas manifold 405 through the showerhead 410 or from other ports (not shown) into the reaction chamber 400. Unreacted gasses and gaseous reaction by-products exit from the bottom of the reaction chamber through an exhaust line 413. The reaction chamber may optionally be equipped with a purge line and/or a pump line coupled to a vacuum pump so that the chamber may be purged between the various reaction cycles (not shown). The apparatus also comprises a controller 414 operably connected to the first, second, and third gas valves 416-418 on the first gas manifold 401, the first and second gas values 409 and 420 on the second gas manifold 405, the RF power source for the RPU 419, the second optional RF power source 415, and other components (not shown).

The controller 414 is configured and programmed to independently control (e.g., turn on and off, etc.) the supply of the various gasses (e.g., carrier gas, first precursor, reactive gas, and any dilutant, process, feed, and/or purging gasses etc.), the low-power plasma source, and optionally the second plasma source, as required, to deposit a film on the surface of the wafer 412. For example, in some embodiments, the controller 414 is configured to open valve 416 to flow the carrier gas from the first carrier gas source 402 into the reaction chamber, then open valve 417 to flow the first precursor from the first source 403 into the reaction chamber and to turn on the RF power supply 409 in the RPU. Turning on the RF power 409 and opening valve 417 may be done one after the other, or simultaneously. After a set period of time, the controller 414 closes the valve to the first precursor 417 and turns off the RF power supply 409. Next, the controller 414 opens the valve 419 to flow the reactive gas from the second source 406 into the reaction chamber 400. After a set period of time, the controller 414 closes the valve 419 to the reactive gas 406. The controller 414 is programed to repeat the various process steps to grow a film on the surface of the wafer 411. The controller 414 may be programed to perform other process steps in between these various steps.

In another embodiment, the controller 414 is configured to open valve 416 to flow the carrier gas from the first carrier gas source 402 into the reaction chamber 400, then open valve 417 to flow the first precursor from the first source 403 into the reaction chamber and to turn on the RF power supply 409 in the RPU. Turning on the RF power 409 and opening the valve 417 may be done one after the other, or simultaneously. After a set period of time, the controller 414 closes the valve to the first precursor 417 and turns off the RF power supply 409. Next, the controller 414 opens the valve 419 to flow the reactive gas from the second source 406 into the reaction chamber 400 and, after a set period of time, pulses (turn on, then off) the second RF power source 415. After another set period of time, the controller 414 closes the valve 419 to the reactive gas 406. The controller 414 is programed to repeat the various process steps to grow a film on the surface of the wafer 411. The controller 414 may be programed to perform other process steps in between these various steps.

The semiconductor processing apparatus or system disclosed herein can include additional sources and additional components, which are not shown in FIG. 3 and FIG. 4, such as those typically found on semiconductor processing apparatus. For example, the semiconductor processing apparatus may be provided with one or more heaters and one or more temperature regulators to activate the reactions by elevating the temperature of one or more of the substrate and/or gasses entering into the reaction chamber (e.g., carrier gas, precursor, reactive gas, etc.). The semiconductor processing apparatus may also be provided with a pumping system to purging the reaction chamber in between the various processing steps.

The reaction chamber can form part of an ALD assembly and may be a single wafer reactor or it may comprise one or more multi-station deposition chambers. Alternatively, the reactor may be a batch reactor. The various steps of the method can be performed within a single reaction chamber, or they can be performed in multiple reaction chambers, such as reaction chambers of a cluster tool. In some embodiments, the method is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate, the reactants, the precursors, and other gasses. The reactants, precursors, and other gasses may be introduced into the chamber using a showerhead-type reaction chamber or cross-flow reaction chamber, or a combination thereof.

The above discussion has been provided for purposes of illustration using a two step cycle. The illustrated two step cycle is sufficient to explain the disclosed method, but the skilled artisan will appreciate that the principles and advantages of the embodiments taught herein can be readily extended to more complex ALD processes. The skilled artisan will readily appreciate that each cycle can include additional steps (e.g., a third reactant pulse, fourth reactant pulse, etc., can be introduced), or of the same reactants, and that not all cycles need to be identical (e.g., a third reactant can be introduced every five cycles to incorporate a desired percentage of different elements). Such flexibility is provided and allows for a variety of films to be produced without departing from the spirit of the disclosure.

The methods and systems disclosed herein may be used to deposit a number of films, such as, by way of non-limiting example, silicon (Si) containing films and boron (B) containing films as well as metal containing films, metal oxide containing films, and metal nitride containing films such as films comprising aluminum (Al), molybdenum (Mo), titanium (Ti), hafnium (Hf), tungsten (W), magnesium (Mg), tantalum (Ta), strontium (Sr), and the like. The methods and systems disclosed herein may be used to increase the reactivity of certain precursors such as, by way of non-limiting example, silicon-containing precursors, boron-containing precursors, and metal containing precursors, such as those precursors comprising aluminum, molybdenum, titanium, hafnium, tungsten, magnesium, tantalum, strontium, and the like. The first precursor, and the first radicalized precursor formed therefrom, may comprise one or more of silicon, boron, and a metal selected from the group consisting of aluminum, molybdenum, titanium, hafnium, tungsten, magnesium, tantalum, and strontium. Suitable precursors may include those which are known to be useful in CVD process. In some embodiments, the first precursor may be useful in CVD-type deposition processes, but it may be unreactive in ALD-type deposition processes. In such a case, radicalization of the first precursor makes it reactive in ALD-type deposition processes.

The methods and systems disclosed herein may be used to deposit silicon (Si) containing films, such as, by way of non-limiting example, low dielectric constant (k) films, high k gate silicates, low temperature silicon epitaxial films, and films comprising silicon nitride, silicon oxynitride, silicon oxycarbonitride, silicon carbonitride, silicon carbide, silicon oxycarbide, and silicon oxide. In some embodiments the Si-containing film is selected from the group consisting of silicon nitride, silicon oxynitride, silicon oxycarbonitride, silicon carbonitride, silicon carbide, silicon oxycarbide, silicon oxide, and combinations thereof. In some embodiments, the Si-containing film is selected from the group consisting of silicon oxycarbonitride, silicon carbonitride, and combinations thereof. In these embodiments, the first precursor, and hence the first radicalized precursor formed therefrom, comprises silicon. In some embodiments, the first precursor comprises silicon and may further comprise one more of carbon (C), hydrogen (H), nitrogen (N), oxygen (O), and halogen (X, where X may be a fluorene (F), chlorine (Cl), bromine (Br) or iodine (I)). The silicon-containing precursor may comprise one or more Si—C bond(s), Si—H bond(s), Si—N bond(s), Si—O bond(s), and Si—X bond(s). Suitable silicon-containing precursors may be selected from a silane, a halosilane, an aminosilane, a silicon alkoxide, a siloxane, and combinations thereof. In some embodiments, the silicon-containing precursor is a silane. A silane contains silicon and hydrogen and may optionally also comprise one or more carbon, oxygen, nitrogen, and halogen atoms. Examples of silanes include monosilanes (SiH₄₋ₙ(R)ₙ, where n is an integer from 0 to 4), disilanes (S₂H₆₋ₙ(R)ₙ, where n is an integer from 0 to 6), and trisilane (S₃H₈₋ₙ(R)ₙ, where n is an integer from 0 to 8) and so on, where each R is an independently selected substituent, preferably an alkyl group or aryl group. Examples of suitable silane precursors are silane (SiH₄), disilane (Si₂H₆), and organo silanes such as dimethylsilane (H₂Si(CH₃)₂), diethylsilane (H₂Si(C₂H₅)₂), trimethylsilane (HSi(CH₃)₃), triethylsilane (HSi(C₂H₅)₃), and the like. In some embodiments, the silicon-containing precursor is a halosilane. A halosilane contains at least one halogen atom bonded to a silicon atom (Si—X) and may also optionally comprise one or more hydrogen, carbon, oxygen, and nitrogen atoms. Examples of halosilanes include halosilanes, halodisilanes (Si—Si), halotrisilane (Si—Si—Si), and so on. Examples of suitable halosilane precursors are dichlorosilane (SiH₂Cl₂), dibromosilane (SiH₂Br₂), diiodosilane (SiH₂I₂), hexachlorodisilane (Si₂Cl₆), octachlorotrisilane (Si₃Cl₈), and the like. In some embodiments, the silicon-containing precursor is an aminosilane. An aminosilane (or silylamine) includes at least one nitrogen atom bonded to a silicon atom (Si—N) and carbon and/or hydrogen and may also optionally comprise one or more oxygen and halogen atoms. Examples of aminosilanes include mono-, di-, tri- and tetra-aminosilanes (e.g., H₃Si(NH₂), H₂Si(NH₂)₂, HSi(NH₂)₃, and Si(NH₂)₄, respectively), silazanes (e.g., NH(SiH₃)₂) and trisilylamines (e.g., N(SiH₃)₂)) as well as substituted linear and cyclic derivatives thereof wherein one or more hydrogen atom on the amino group and/or the silane group are independently substituted with a substituent group (R), preferably an alkyl group or aryl group. Examples of aminosilane are bis(diethylamino)silane (C₈H₂₂N₂Si), diisopropylaminosilane (C₆H₁₇NSi), N-(diethylaminosilyl)-N-ethylethanamine (C₈H₂₂N₂Si), hexamethylcyclotrisilazane (C₆H₂₁N₃Si₃), and the like. In some embodiments, the silicon-containing precursor is a silicon alkoxide. A silicon alkoxide includes at least one Si—O—C linkage may also optionally comprise one or more hydrogen, nitrogen, and halogen atoms. Examples of silicon alkoxide include mono-, di-, tri- and tetra-silicon alkoxide (e.g., H₃SiOCH₃), H₂Si(OCH₃)₂, HSi(OCH₃)₃, and Si(OCH₃)₄, respectively) as well as substituted linear and cyclic derivatives thereof wherein one or more hydrogen atoms on the methyl group and/or the silane group are independently substituted with a substituent group (R), prefer an alkyl group or an aryl group. Examples of silicon alkoxide precursors are tetraethylorthosilicate (TEOS, Si(OC₂H₅)₄), dimethoxydimethylsilane (Si(OCH₃)₂(CH₃)₂), trimethoxymethylsilane (Si(OCH₃)₃CH₃), and the like. In some embodiments, the silicon-containing precursor is a siloxane. A siloxane includes at least one Si—O—Si linkage, and may optionally also contain one or more hydrogen, carbon, and halogen atoms. Examples of siloxane include linear and cyclic siloxanes, such as cyclotrisiloxanes, cyclotetrasiloxanes, and silsesquioxanes. Examples of suitable siloxane precursors are include octamethylcyclotetrasiloxane (OMCTS, C₈H₂₄O₄Si₄), 1,1,3,5,5,7-hexamethylcyclotetrasiloxane (HMCTS, C₈H₂₄O₃Si₄), 1,3,5,7-tetramethyl-cyclotetrasiloxane (TMCTS, C₄H₁₆O₄Si₄), and the like. In some embodiments, the silicon containing precursors is selected from the group consisting of dimethylsilane, diethylsilane, trimethylsilane, triethylsilane, dichlorosilane, diiodosilane, hexachlorodisilane, octachlorotrisilane, bis(dimethylamino)silane, bis(diethylamino)silane, diisopropylaminosilane, N-(diethylaminosilyl)-N-ethylethanamine, hexamethylcyclotrisilazane, tetraethylotrhosilicate, dimethoxydimethylsilane, trimethoxymethylsilane, octamethylcyclotetrasiloxane, 1,1,3,5,5,7-hexamethylcyclotetrasiloxane, 1,3,5,7-tetramethylcyclotetrasiloxane, and combinations thereof.

The methods and systems disclosed herein may be used to deposit boron (B) containing films, such as, by way of non-limiting example, hard masks, low dielectrics, lining layers, boron-doped films (e.g., borosilicate glass), and films comprising boron nitride, boron carbide, borocarbonitride, and boron oxide. In some embodiments, the boron-containing film is selected from the group consisting of boron nitride, boron carbide, borocarbonitride, boron oxide, and combinations thereof. In some embodiments, the boron-containing film is amorphous boron nitride. In these embodiments, the first precursor, and the first radicalized precursor formed therefrom, comprises boron. In some embodiments, the first precursor comprises boron and may further comprise one more of carbon (C), hydrogen (H), nitrogen (N), and oxygen (O). The boron-containing precursor may comprise one or more B—C bond(s), B—H bond(s), B—N bond(s), and B—O bond(s). In some embodiments, the boron-containing precursor consists of boron and a halogen. The halogen may be selected from a group consisting of fluorine (F), chlorine (Cl), bromine (Br) and iodine (I). In some embodiments, the halogen is selected from a group consisting of chlorine (Cl), bromine (Br) and iodine (I). In some embodiments, the halogen is selected from a group consisting of chlorine (Cl), and bromine (Br). In some embodiments, the boron-containing precursor consists of boron and a halogen. In some embodiments, the boron-containing precursor is selected from a group consisting of boron trihalides. In some embodiments, the boron-containing precursor comprises BCl₃. In some embodiments, the boron-containing precursor comprises BBr₃

Further suitable boron-containing precursors may be selected from a borane, an alkyl borane, an aryl borane, a carbborane, an amine or amino borane, a borate ester, a borazine, and a combination thereof. In some embodiments, the boron-containing precursor is a borane (BₓH_{Y}). Examples of suitable borane precursors are diborane (B₂H₆), tetraborane (B₄H₁₀), pentaborane (B₅H₉), decaborane (B₁₀H₁₄), octadecaborane (B₁₈H₂₂), and the like. In some embodiments, the borane precursor is substituted with one or more alkyl group(s), aryl group(s), and combinations thereof. For example, one or more hydrogen atoms in a borane may be substituted with an alkyl group and/or an aryl group. Examples of suitable alkyl and aryl borane precursors include trimethyl borane (B(CH₃)₃), triethyl borane (B(C₂H₅)₃), triphenyl borane (B(C₆H₅)₃), and the like. In some embodiments, the boron-containing precursor is a carborane. A carborane contains boron, carbon, and hydrogen and may optionally be substituted with one or more oxygen, nitrogen, and halogen atoms. Examples of suitable carborane precursors are nido-carborane (C₂B₄H₈), ortho-carborane (C₂B₁₀H₁₂), and the like. In some embodiments, the boron-containing precursor is an amine or amino borane. Examples of amine boranes include ammonia borane (NH₃BH₃) and substituted derivatives thereof (e.g., NRₙH₃₋ₙBH₃, where n is an integer from 1 to 3 and each R is independently a substituent group, preferably an alkyl group or an aryl group). Examples of amino boranes include mono-, di-, tri-amino borane (e.g., H₂B(NH₂), HB(NH₂)₂, and B(NH₂)₃, respectfully) and linear and cyclic substituted derivatives thereof (e.g., H₂B(NHR), H₂B(NR₂), HB(NHR)₂, HB(NR₂)₂, B(NHR)₃, and B(NR₂)₃, where each R is independently a substituent group, preferably an alkyl group or an aryl group). Examples of suitable amine and amino borane precursors are ammonia borane (NH₃BH₃), methylamine borane (CH₃NH₂BH₃), dimethylamine borane ((CH₃)₂NHBH₃), trimethylamine borane ((CH₃)₃NBH₃), t-butylamine borane ((CH₃)₃CNH₂BH₃), tris(dimethylamino)borane (B(N(CH₃)₂)₃), B(cycloriborazanyl)amine borane (B₄N₄H₁₆), and the like. In some embodiments, the boron-containing precursor is a borate ester. Examples of borate esters include ortho borates such as boronic esters (BR₂(OR)), boronic esters (BR₂(OR)), and borates (B(OR)₃) and metaborates (B₃O₃(OR)₃), where each R is independently a substituent group, preferably an alkyl group or an aryl group. Examples of suitable borate ester precursors are trimethyl borate (B(OCH₃)₃), triethyl borate (B(OCH₂CH₃)₃), and the like. In some embodiments, the boron-containing precursor is borazine or a substituted borazine. Borazine has the chemical structure B₃H₆N₃. In substituted borazines one or more H atoms are replaced with a substituent group (R), preferably an alkyl group or an aryl group. Additionally, or alternatively, one or more boron or nitrogen atoms in the borazine ring may be substituted with a carbon atom. Examples of suitable borazine precursors are borazine (B₃H₆N₃), 2,4,6-trichloroborazine (B₃H₃Cl₃N₃), 2,4,6-tribromoborazine (B₃H₃Br₃N₃), and the like. In some embodiments, the boron containing precursor is selected from the group consisting of nido-carborane, ortho-carborane, ammonia borane, dimethylamine borane, trimethylamine borane, t-butylamine borane, tris(dimethylamino)borane, B(cycloriborazanyl)amine borane, trimethyl borate, triethyl borate, borazine, 2,4,6-trichloroborazine, 2,4,6-tribromoborazine, diborazine, and combinations thereof.

In some embodiments, the reactive gas may be an oxygen containing gas. For example, the oxygen containing gas may be selected from one or more of oxygen (O₂), ozone (O₃), water (H₂O), hydrogen peroxide (H₂O₂), an alcohol (ROH, where R is an alkyl or aryl group) such as methanol (CH₃OH) and ethanol (C₂H₅OH), nitrogen dioxide (NO₂), nitrous oxide (N₂O), and oxygen atoms (O*) created in a plasma. In some embodiments, the reactive gas may be a nitrogen containing gas. For example, the nitrogen containing gas may be selected from one or more of ammonia (NH₃), hydrazine (N₂H₄), nitric oxide (NO), and activated nitrogen (N₂), activated ammonia (NH₃), and nitrogen atoms (N*) created in a plasma. In some embodiments, the reactive gas may be selected from one or more of hydrogen (H₂) and hydrogen atoms (H*) created in a plasma. In some embodiments, the reactive gas comprises one or more of O₂, H₂O, NH₃, and H₂. In some embodiments, the reactive gas may comprise O*, N*, H*, and combinations thereof.

The methods and systems disclosed herein can provide several benefits, including enhanced precursor reactivity which may reduce the processing time to obtain a desired film thickness and/or the number of the cycles needed to obtain the desired film thickness. It also may allow for deposition to occur under lower temperature processing conditions. The methods and systems may also improve the uniformity and conformality of the film. Without wishing to be bound by a particular theory, the radicalized first precursor is more reactive and it may also be smaller in size compared to the parent precursor from which it is derived; this may result in a higher degree of surface coverage on the substrate, thus leading to faster growth, higher uniformity, and improve conformity, which may occur, for example, on sidewalls of trench structures.

### EXAMPLES

### Example 1: Use of TMCTS as an ALD Precursor

The methods and systems disclosed herein can be used to enable the use of relatively “non-reactive” precursors that may not readily chemisorb on a substrate surface and/or participate in thermal ALD reactions. For example, 2,4,6,8-tetramethylcyclotetrasiloxane (TMCTS) is a precursor that is commonly used in CVD deposition process; however, no ALD process is available using this precursor.

An SiOC film was grown on the surface of an Si wafer by sequentially pulsing TMCTS precursor and O₂ reactive gas into to a reaction chamber. TMCTS was pulsed into an argon or helium 20 W RF plasma discharge. The plasma discharge was provided in the upper portion of the reaction chamber and separated from the Si wafer by an electrically grounded mesh plate. Next, O₂ was introduced into the reaction chamber and a 100 W RF plasma was pulsed. The reaction chamber was purged in between precursor and reactive gas pulses.

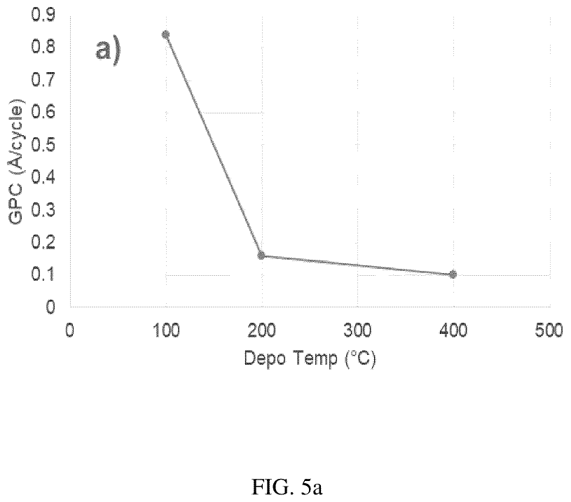

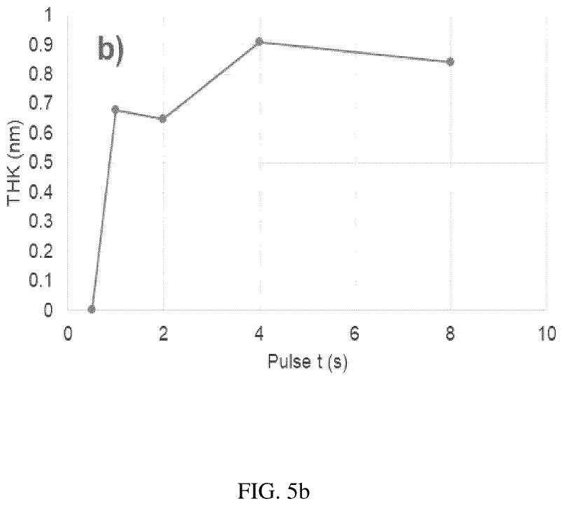

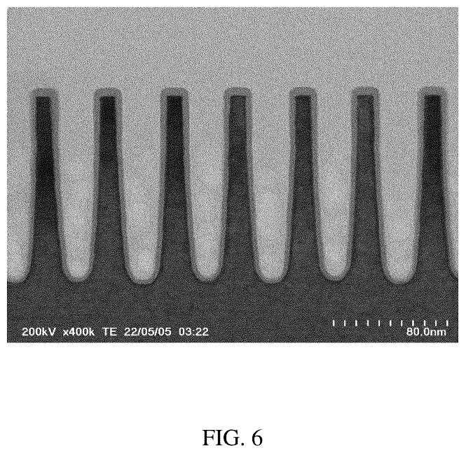

FIG. 5 shows the (a) GPC of the process at the tested temperature range (FIG. 5a) as well as (b) an ALD saturation curve for the He radicalization process at 400° C. (FIG. 5b). Deposition occurred at temperatures below 400° C., with the GPC increasing as the temperature decreases. At precursor pulse times of 4 seconds and longer, the film thickness was essentially constant. The film thickness was lesser at shorter precursor pulse times, likely due to incomplete saturation of the reaction sites at these shorter times. It is clear from the graphs that the process shows ALD behavior, enabling the use of TMCTS as an ALD precursor. The conformality of the deposited films was also tested (see FIG. 6), and it was found to be roughly 70%, which is a fairly good value for an unoptimized ALD process. Notably, the thickness at the bottom of the trenches is also lower than on the top, which is unlike due to CVD and suggests that the non-ideal conformality may be due to a lack of process saturation in the ALD cycle. While the growth rate of the film was rather low, the results serve as a proof of concept and with the optimized process conditions and/or another precursor it should be possible to create a feasible process for commercial applications.

### Example 2: Enhanced Deposition Using SAM-24 Precursor

The methods and systems disclosed herein can increases the reactivity of a precursor and improve the uniformity of the resulting film.

An SiO₂ film was grown on the surface of an Si wafer at 400° C. by sequentially pulsing N-(diethylaminosilyl)-N-ethylethanamine (SAM-24) precursor and O₂ reactive gas into to a reaction chamber. The precursor, SAM-24, was pulsed into an argon or helium 20 W RF plasma discharge.

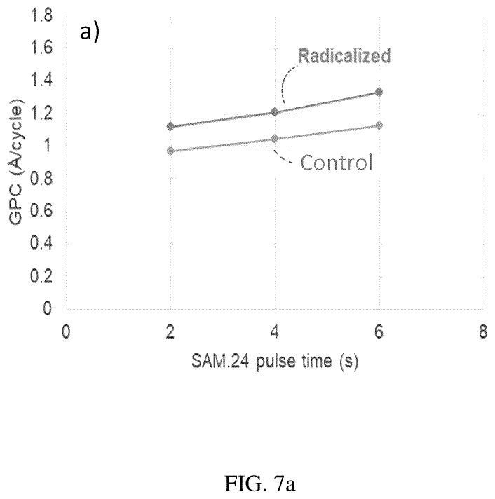

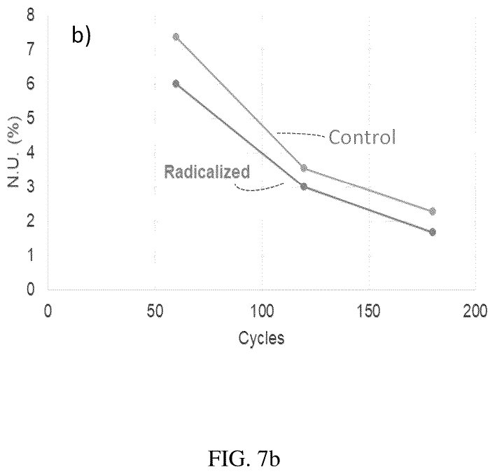

The plasma discharge was provided in the upper portion of the reaction chamber and separated from the Si wafer by an electrically grounded mesh plate. Next, O₂ was introduced into the reaction chamber and a 100 W RF plasma was pulsed. The reaction chamber was purged in between precursor and reactive gas pulses. A control experiment was performed, using a similar method, by introducing the SAM-24 precursor and O₂ reactive gas into to a reaction chamber, but the SAM-24 precursor was not subjected to the low-power plasma discharge. FIG. 7 shows (a) the GPC of the process over a range of precursor pulse times (FIG. 7a) as well as (b) the non-uniformity per cycle for deposition at 400° C. for using both radicalized SAM-24 precursor and non-radicalized (i.e., control) SAM-24 precursor (FIG. 7b). No sign of CVD growth was observed on the substrate, but the growth rate of the film produced using the radicalized precursor was increased by 10-20% compared non-radicalized precursor process. Surprisingly, the film produced using the radicalized precursor process consistently displayed a lower non-uniformity compared the film formed using the non-radicalized precursor. This may, in part, be due to the smaller size of the radicalized precursor which improves the surface coverage. The optical properties as well as the wet etch rate of the two films was similar, indicating that the quality of the films is identical despite the improved growth characteristics.

Although certain embodiments and examples are disclosed herein, it will be understood by those skilled in the art that the disclosed methods and systems extend beyond the specifically disclosed embodiments and include all novel and nonobvious combinations and sub-combinations of the various processes, systems, and configurations, as well as any and all equivalents thereof. It is to be understood that the methods and/or systems described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases. Moreover, various features of the disclosure are grouped together in one or more, aspects, embodiments, and configurations for the purpose of streamlining the disclosure. The features of the aspects, embodiments, and configurations of the disclosure may be combined in alternate aspects, embodiments, and configurations other than those discussed above. The methods and systems of disclosure is not to be interpreted as reflecting an intention that the claimed disclosure requires more features than are expressly recited in each claim. Rather, as the following claims reflect, inventive aspects lie in less than all features of a single foregoing disclosed aspects, embodiments, and configurations. Thus, the following claims are hereby incorporated into this Detailed Description, with each claim standing on its own as a separate preferred embodiment of the disclosure.

1. A method for forming a film on a surface of a substrate, comprising:
providing a substrate in a reaction chamber;
providing a first precursor into a low-power plasma discharge to form a radicalized first precursor;
contacting a surface of the substrate with the radicalized first precursor, wherein at least a portion of the radicalized first precursor chemisorbs onto the surface of the substrate to form a chemisorbed layer and wherein the chemisorption is self-limited;
purging the reaction chamber;
contacting the surface of the substrate with a reactive gas, wherein at least a portion of the reactive gas reacts with the chemisorbed layer to form a film; and
purging the reaction chamber.

2. The method of claim 1, further comprising: repeating the contacting steps and the purging steps to grow the film to a targeted thickness.

3. The method of claim 1, wherein the step of contacting the surface of the substrate with the radicalized first precursor occurs in the substantial absence of charged species.

4. The method of claim 1, wherein an ion trap is provided in the reaction chamber between the low-power plasma discharge and the substrate.

5. The method of claim 1, wherein the low-power plasma discharge is produced by gas-phase ionization of a gas with a radio frequency (RF) power of 100 W or less.

6. The method of claim 1, further comprising: providing a second plasma discharge.

7. The method of claim 6, wherein the second plasma discharge is produced by gas-phase ionization of a gas comprising the reactive gas with a radio frequency (RF) power of at least 20 W and less than 200 W.

8. The method of claim 1, wherein a temperature of the substrate is at least 40° C. and no more than 450° C.

9. The method of claim 1, wherein the first precursor comprises silicon.

10. The method of claim 9, wherein the first precursor is selected from the group consisting of: a silane, a halosilane, an aminosilane, a silicon alkoxide, a siloxane, and combinations thereof.

11. The method of claim 9, wherein the first precursor is selected from the group consisting of: dimethylsilane, diethylsilane, trimethylsilane, triethylsilane, dichlorosilane, diiodosilane, hexachlorodisilane, octachlorotrisilane, bis(dimethylamino)silane, bis(diethylamino)silane, diisopropylaminosilane, N-(diethylaminosilyl)-N-ethylethanamine, hexamethylcyclotrisilazane, tetraethylotrhosilicate, dimethoxydimethylsilane, trimethoxymethylsilane, octamethylcyclotetrasiloxane, 1,1,3,5,5,7-hexamethylcyclotetrasiloxane, 1,3,5,7-tetramethylcyclotetrasiloxane, and combinations thereof.

12. The method of claim 1, wherein the first precursor comprises boron.

13. The method of claim 12, wherein the first precursor is selected from the group consisting of: a borane, an alkyl borane, an aryl borane, a carborane, an amine borane, an amino borane, a borate ester, a borazine, and combinations thereof.

14. The method of claim 1, wherein the reactive gas comprises one or more of oxygen, ozone, water, hydrogen peroxide, an alcohol, nitrogen dioxide, nitrous oxide, oxygen atoms, ammonia, hydrazine, nitric oxide, nitrogen atoms, hydrogen, and hydrogen atoms.

15. The method of claim 1, wherein the film is selected from the group consisting of: silicon nitride, silicon oxynitride, silicon oxycarbonitride, silicon carbonitride, silicon carbide, silicon oxycarbide, silicon oxide, and combinations thereof.

16. A semiconductor processing apparatus, comprising:
a reaction chamber for accommodating a substrate;
a first source for a first precursor in gas communication via a first valve with the reaction chamber;
a second source for a reactive gas in gas communication via a second valve with the reaction chamber;
a plasma unit comprising an RF power source; and
a controller operably connected to the first valve, the second valve, and the plasma unit,
configured and programmed to control:
supplying the first precursor in the reaction chamber; and
activating the plasma unit to supply a low-power plasma discharge in the reaction chamber to form a radicalized first precursor from the first precursor, wherein at least a portion of the radicalized first precursor chemisorbs onto a surface of the substrate to form a chemisorbed layer and wherein the chemisorption is self-limited; and
supplying the reactive gas into the reaction chamber, wherein at least a portion of the reactive gas reacts with the chemisorbed layer.

17. The semiconductor processing apparatus of claim 16, wherein the low-power plasma discharge is produced by gas-phase ionization of a gas with a radio frequency (RF) power of 100 W or less.

18. The semiconductor processing apparatus of claim 16, wherein the plasma unit is a remote plasma unit.

19. The semiconductor processing apparatus of claim 16, further comprising an electrically grounded mesh plate positioned between the low-power plasma discharge and the substrate.

20. The semiconductor processing apparatus of claim 16, further comprising: a second plasma unit comprising a second RF power source, wherein the controller is further configured and programmed to control activating the second plasma unit to supply a second plasma discharge, wherein the second plasma discharge is produced by gas-phase ionization of a gas comprising the reactive gas with a radio frequency (RF) power of at least 20 W and less than 1,000 W.
